(19) United States
(12) Patent Application Publication
(10) Pub. No.: US 2019/0304919 A1
(43) Pub. Date: Oct. 3, 2019

(54) HYBRID METAL INTERCONNECT STRUCTURES FOR ADVANCED PROCESS NODES

(71) Applicant: QUALCOMM Incorporated, San Diego, CA (US)

(72) Inventors: John ZHU, San Diego, CA (US); Da YANG, San Diego, CA (US); Stanley Seungchul SONG, San Diego, CA (US); Kern RIM, San Diego, CA (US)

(21) Appl. No.: 15/936,964

(22) Filed: Mar. 27, 2018

(51) Int. Cl. H01L 23/532; H01L 23/522; H01L 21/768; H01L 21/285

(52) U.S. Cl. CPC H01L 23/53266; H01L 23/5226; H01L 21/76802; H01L 21/76847; H01L 23/53238; H01L 21/7684; H01L 21/28556; H01L 21/76877

(57) ABSTRACT

Aspects of the disclosure are directed to an integrated circuit. The integrated circuit may include a metal contact comprising a first hybrid interconnect structure disposed within a metallization layer, and a metal comprising a second hybrid interconnect structure disposed within the metallization layer, wherein each of the first and the second hybrid interconnect structures has a top portion and a bottom portion, and wherein the top portion of each of the first and the second hybrid interconnect structures comprises a metal element that is suitable for chemical mechanical planarization (CMP) and the bottom portion of each of the first and the second hybrid interconnect structures comprises ruthenium (Ru). The metal element may comprise cobalt (Co).

### BACKGROUND

### Field

Aspects of the present disclosure relate generally to semiconductor structures and, more particularly, to hybrid conductors and methods of making the same.

### Background

Copper (Cu) is a commonly used material for metallization layers. Copper has high electrical conductivity providing for relatively low resistance and good integrated chip performance. Copper metallization layers (e.g., metal wires and vias) are often formed using a damascene process in which copper is deposited into a patterned dielectric material. For example, in a dual damascene process a dielectric material is deposited over a semiconductor substrate. The dielectric material is etched to form openings for a via (e.g., through a via hole) and a metal wire (e.g., through a metal trench). The openings are then filled with copper and a planarization process is performed to remove excess copper from the substrate. As technology nodes continue to advance down to 7 nm and beyond, the size of integrated chip components and metalation layers continue to decrease. Less scaled copper barrier and liner reduce copper portion in conductor and increase effective copper resistivity and hence copper conductor resistance. Similarly, the dimensions of vias and metal wires become smaller making it increasingly difficult for damascene processes to fill the via holes and/or metal trenches with copper. As a result, voids may be formed that may lead to electrical opens, and/or high electrical resistance in a metallization layer. Ruthenium (Ru) may be used as a conductor material with superior filling capability, thin adhesion layer requirement, and moderate resistivity. However, chemical mechanical planarization (CMP) is very challenging for ruthenium. Thus, there is a need for an improved or integrated hybrid material for metallization layers for advanced process nodes.

### SUMMARY

The following presents a simplified summary of one or more embodiments to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A method of forming a metallization layer for advanced process nodes according to one embodiment is described. The method of forming a metallization layer may comprise selectively etching an interlayer dielectric (ILD) layer to form a first metal opening, partially filling the first metal opening from the bottom-up with a first conductive material such as ruthenium (Ru), filling the partially filled first metal opening with a sacrificial dielectric, selectively etching the interlayer dielectric (ILD) layer to form a second metal opening, removing the sacrificial dielectric from the first metal opening, partially filling ruthenium (Ru) to both the first and the second metal openings, filling top portions of the first and the second metal openings with cobalt (Co), and removing excess from the first and the second metal openings thereby forming the first and the second interconnect structures.

An integrated circuit according to one embodiment is described. The integrated circuit may include a metal contact comprising a first hybrid interconnect structure disposed within a metallization layer, and a metal comprising a second hybrid interconnect structure disposed within the metallization layer, wherein each of the first and the second hybrid interconnect structures has a top portion and a bottom portion, and wherein the top portion of each of the first and the second hybrid interconnect structures comprises a metal element that is suitable for chemical mechanical planarization (CMP) and the bottom portion of each of the first and the second hybrid interconnect structures comprises ruthenium (Ru). The metal element may comprise cobalt (Co).

These and other embodiments of the invention will become more fully understood upon a review of the detailed description, which follows. Other embodiments of the invention will become apparent to those of ordinary skill in the art, upon reviewing the following description of specific, exemplary embodiments of the invention in conjunction with the accompanying figures.

### BRIEF DESCRIPTION OF THE DRAWINGS

FIG. 1 illustrates a cross-section view of a metallization layer including metal interconnect structures of the prior art;

FIGS. 2A-2C illustrate cross-section views of a metallization layer of an integrated chip including hybrid metal interconnect structures in accordance to one embodiment of the invention; and

FIGS. 3A-3H illustrate a method of forming a metallization layer of an integrated chip including hybrid metal interconnect structures in accordance to one embodiment of the invention.

### DETAILED DESCRIPTION

The detailed description set forth below, in connection with the appended drawings, is intended as a description of exemplary embodiments and is not intended to represent the only embodiments in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

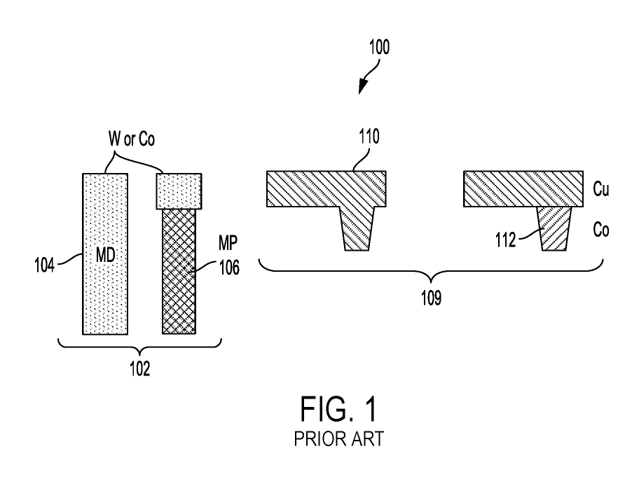

FIG. 1 illustrates a cross-section view of a metallization layer 100 including metal interconnect structures of the prior art. Interconnect structures may include contact metal 102 and metal/via (metal and/or via) 109. Contact metal 102 may further comprise contact (MD) to source/drain 104 and contact (MP) to gate 106. Metal/via 109 may further comprise metal wire 110 and via 112. Metallization layer 100 may be formed. over a substrate comprising; any type of semiconductor material such as a semiconductor wafer or one or more die on a wafer. Furthermore, metallization layer 100 may be disposed in a dielectric layer such as a low-k material or an ultra-low-k (ULK) dielectric material. Via 112 may be configured for vertical interconnections, and metal wire 110 may be configured for lateral interconnections. Interconnect structures of the prior art (e.g., contact (MD) to source/drain 104 and contact (MP) to gate 106 of contact metal 102, and metal wire 110 and via 112 of metal/via 109) may comprise of cobalt (Co) or copper (Cu). Drawbacks for cobalt and copper as a contact metal or metal include thick barrier seed liner or adhesion layer, voids that may form due less-than-perfect metal fills, and electrical mechanical (EM) challenges. In addition, when deposited by chemical vapor deposition (CVD), cobalt and copper volume portion in conductor do not scale for advanced nodes as dimensions of metal wires and vias become smaller as compared to current nodes. As such, there is a need for an integrated hybrid material for hybrid metal interconnect structures for metallization layers for advanced process nodes to improve metal fills, overcome process difficulties, and lower electrical resistance.

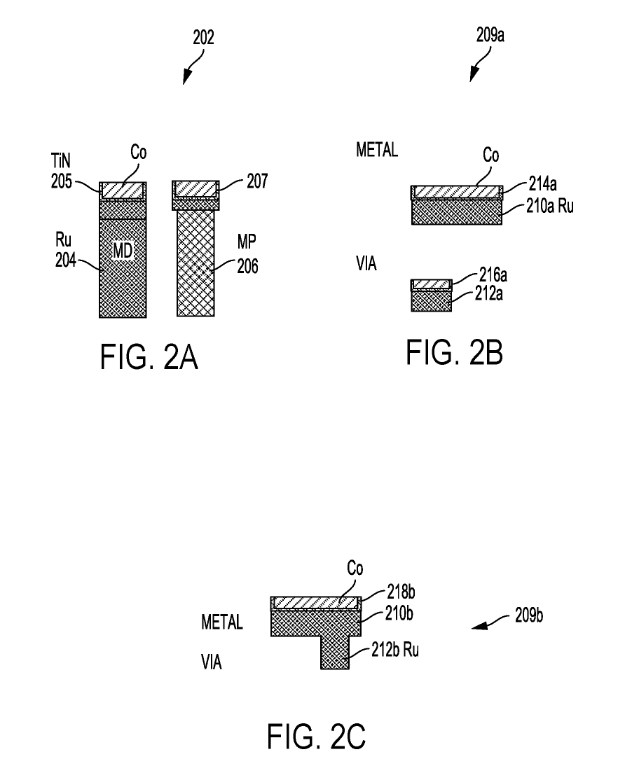

FIGS. 2A-2C illustrate cross-section views of a metallization layer of an integrated chip including hybrid metal interconnect structures in accordance to one embodiment of the invention. The hybrid interconnect structures may include contact metal 202. Contact metal 202 may further comprise contact (MD) to source/drain 204 and contact (MP) to gate 206 as illustrated in FIG. 2A. The hybrid interconnect structures may further include metal/via 209a formed in a single damascene process as illustrated in FIG. 2B, or metal/via 209b formed in a dual damascene process as illustrated in FIG. 2C. Metal/via 209a may further comprise metal wire 210a and via 212a. Similarly, metal/via 209b may further comprise metal wire 210b and via 212b. Single and dual damascene processes are further described below. The metallization layer including hybrid metal interconnect structures (e.g., contact (MD) to source/drain 204 and contact (MP) to gate 206 of contact metal 202, and metal wires 210a/210b and vias 212a/212b of metal/via 209a/209b, respectively) may be formed over a substrate comprising any type of semiconductor material such as a semiconductor wafer or one or more die on a wafer. The metallization layer may be disposed in a dielectric layer such as a low-k material or an ultra-low-k (ULK) dielectric material. Vias 212a/212b may be configured for vertical interconnections, and metal wires 210a/210b may be configured for lateral interconnections.

In one embodiment, contact (MD) to source/drain 204 may be a hybrid interconnect structure having a top portion comprising cobalt (Co) or copper (Cu), and a bottom portion comprising ruthenium (Ru) as illustrated in FIG. 2A. Similarly, contact (MP) to gate 206 may be a hybrid interconnect structure having a top portion comprising cobalt (Co) and a bottom portion comprising ruthenium (Ru). In another embodiment, metal wire 210a may be a hybrid interconnect structure having a top portion comprising cobalt (Co) or copper (Cu) and a bottom portion comprising ruthenium (Ru) as illustrated in FIG. 2B. Similarly, via 212a may be a hybrid interconnect structure having a top portion comprising cobalt (Co) and a bottom portion comprising ruthenium (Ru). Metal wire 210a and via 212a may be formed in a single damascene process. In yet another embodiment, metal/via 209b may be a hybrid interconnect structure having metal wire 210b and via 212b formed in a dual damascene process as illustrated in FIG. 2C. In one dual damascene process embodiment, metal wire 210b may have a top portion comprising cobalt (Co) or copper (Cu), and a bottom portion comprising ruthenium (Ru), and via 212b comprising ruthenium (Ru). In another dual damascene process embodiment, via 212b may have a top portion comprising cobalt (Co) and a bottom portion comprising ruthenium (Ru), and metal wire 210b comprising ruthenium (Ru). In each of the above embodiments, the hybrid interconnect structures of the invention, e.g., contact (MD) to source/drain 204, contact (MP) to gate 206, metal wire 210a, via 212a, and metal/via 210b/212b, may further include a thin barrier seed layer 205, 207, 214a, 216a, and 218b, respectively, comprising titanium nitride (TiN), tantalum (Ta), or tantalum nitride (TaN).

The hybrid interconnect structures of the invention (e.g., contact (MD) to source/drain 204, contact (MP) to gate 206, metal wire 210a, via 212a, and metal/via 210b/212b) may be formed by depositing cobalt (Co) on a top portion and ruthenium (Ru) on a bottom portion of each of the hybrid interconnect structures by chemical vapor deposition (CVD) as further described below. Together, the bilayer of Co and Ru improve metal fills, avoid Ru CMP process difficulties, and lower electrical resistance for advanced process nodes. For example, benefits of ruthenium (Ru) as a contact metal include a very thin adhesion layer of approximately 0.5 nm, no barrier seed layer, superior metal fill capability, and superior reliability as compared to cobalt and/or copper alone. In another embodiment as described above, each of the hybrid interconnect structures, e.g., contact (MD) to source/drain 204, contact (MP) to gate 206, metal wire 210a, via 212a, and metal/via 210b/212b, may include a thin barrier seed layer 205, 207, 214a, 216a, and 218b, respectively, comprising, titanium nitride (TiN), tantalum (Ta), or tantalum nitride (TaN). The metallization layer including the hybrid metal interconnect structures of the invention may have a width of approximately 10-20 nm.

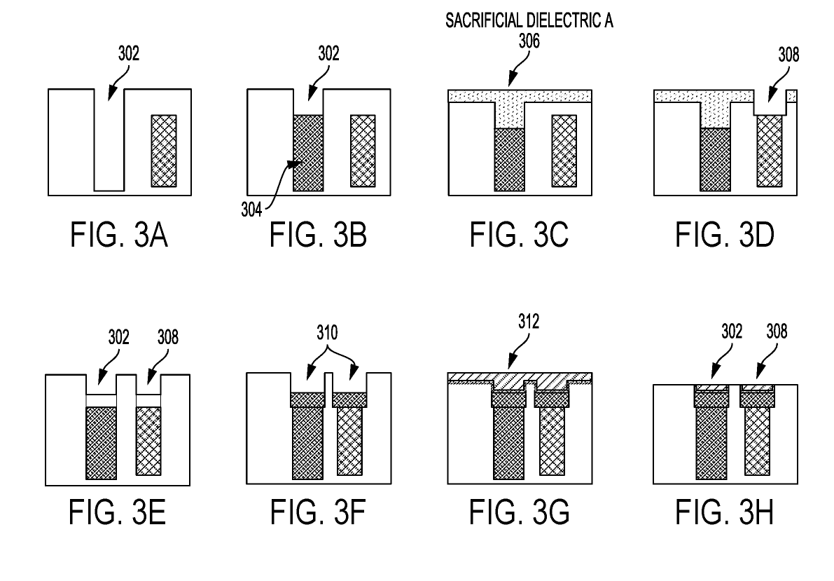

FIGS. 3A-3H illustrate a method 300 of forming a metallization layer of an integrated chip including hybrid metal interconnect structures, e.g., interconnect structures shown in FIGS. 2A-2C, in accordance to one embodiment of the invention. While disclosed method 300 is illustrated and described as a series steps, the ordering of such steps are not to be limited to such order. For example, some steps may occur in different orders and/or concurrently with other steps apart from those illustrated and described herein. In FIG. 3A, there is shown an interlayer dielectric (ILD) layer of a first interconnect structure (e.g., contact (MD) to source/drain 204 in FIG. 2) that may be selectively (by first patterning) etched to form first metal opening(s) 302 within the ILD layer. The ILD layer is preferably a low-k dielectric layer having a dielectric constant (k value) less than about 4.0. It can also be SiO₂. For example, the ILD layer may be exposed to an etchant that is configured to selectively etch the ILD layer according to a masking layer to form the first metal opening(s) 302. The first metal opening(s) 302 may be openings for contact (MD) to source/drain 204 as shown in FIG. 2. The masking layer may comprise a photoresist layer. The first metal opening(s) 302 may have a width of approximately 30 nm. The etchant may comprise a plasma etchant having an etching chemistry comprising one or more of tetrafluoromethane (CF₄) or octafluorocyclobutane (C₄F₈).

In FIG. 3B, the first metal opening(s) 302 may be partially filled from the bottom-up with a first conductive material 304. The first conductive material 304 may include ruthenium (Ru) deposited using a deposition technique such as a chemical vapor deposition (CVD) process. The CVD process may be performed within a processing chamber held at a temperature in a range of between approximately 100° C. and approximately 300° C. and at a pressure in a range of, e.g., between approximately 10 torr and approximately 50 torr. The CVD process may use processing gases of C₅H₅(CO)₂Co and H₂. Next, in FIG. 3C, the first metal opening(s) 302 may be completely filled by a sacrificial dielectric A 306 comprising of, e.g., SiOCH. In FIG. 3D, the ILD layer of a second interconnect structure may be selectively etched to form second metal opening(s) 308 within the ILD layer. The second metal opening(s) 308 may be openings for contact (MP) to gate 206 in FIG. 2. In FIG. 3E, the dielectric A may be removed from the first metal opening(s) 302. In FIG. 3F, both the first metal opening(s) 302 and the second metal opening(s) 308 may be partially filled with ruthenium (Ru) 310. In FIG. 3G, top portions of both the first metal opening(s) 302 and the second metal opening(s) 308a may be filled with cobalt (Co) 312 forming the first and the second interconnect structures, respectively (i.e., the contact (MD) to source/drain 204 and the contact (MP) to gate 206, respectively, as shown in FIG. 2). Cobalt may be deposited by way of a plating process (e.g., an electro plating process or an electro-less plating process). In other embodiments, copper may be deposited using a vapor deposition technique (e.g., CVD, PVD, ALD, etc.). In FIG. 3H, a chemical mechanical polishing (CMP) process may be performed to remove excess from the first metal opening(s) 302 and the second metal opening(s) 308. It will be appreciated that method 300 may be performed according to a damascene process. The hybrid interconnect structures of the invention (e.g., contact MD) to source/drain 204, contact (MP) to gate 206, metal wire 210a, via 212a, and metal/via 210b/212b) may be implemented as a metal layer or via of a single or dual damascene process.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1. An integrated circuit, comprising:
a contact metal comprising a first hybrid interconnect structure disposed within a metallization layer; and
a metal comprising a second hybrid interconnect structure disposed within the metallization layer,
wherein each of the first and the second hybrid interconnect structures has a top portion and a bottom portion,
wherein the top portion of each of the first and the second hybrid interconnect structures comprises a metal element that is suitable for chemical mechanical planarization (CMP) and the bottom portion of each of the first and the second hybrid interconnect structures comprises ruthenium (Ru),
wherein the metal further comprises a via,
wherein the metal is configured for lateral interconnections, and
wherein the via is configured for vertical interconnections.

2. The integrated circuit of claim 1, wherein the contact metal includes contact to source/drain and contact to gate.

3. The integrated circuit of claim 2, wherein each of the contact to source/drain and the contact to gate has a top portion and a bottom portion.

4. The integrated circuit of claim 3, wherein the top portion of each of the contact to source/drain and the contact to gate comprises cobalt (Co) and the bottom portion of each of the contact to source/drain and the contact to gate comprises ruthenium (Ru).

5. The integrated circuit of claim 2, wherein each of the contact to source/drain and the contact to gate further comprises a barrier seed layer.

6. The integrated circuit of claim 5, wherein the barrier seed layer comprises titanium nitride (TiN), tantalum (Ta), or tantalum nitride (TaN).

7. (canceled)

8. The integrated circuit of claim 1, wherein the via has a top portion and a bottom portion.

9. The integrated circuit of claim 8, wherein the top portion comprises cobalt (Co) and the bottom portion comprises ruthenium (Ru).

10. The integrated circuit of claim 7, wherein the metal and the via are formed in a single damascene process.

11. The integrated circuit of claim 7, wherein the metal and the via are formed in a dual damascene process.

12. The integrated circuit of claim 7, wherein the metal and the via further comprise a barrier seed layer.

13. The integrated circuit of claim 12, wherein the barrier seed layer comprises titanium nitride (TiN), tantalum (Ta), or tantalum nitride (TaN).

14. The integrated circuit of claim 1, wherein the metal element comprises cobalt (Co).

15-24. (canceled)
